(19) United States
(12) Patent Application Publication
(10) Pub. No.: US 2026/0066617 A1
(43) Pub. Date: Mar. 5, 2026

(54) COUPLED CAVITY LASER

(71) Applicant: Apple Inc., Cupertino, CA (US)

(72) Inventors: Daniel Mahgerefteh, Campbell, CA (US); Tomas Sarmiento, Mountain View, CA (US); Lucia Gan, Mountain View, CA (US); Edward Vail, Menlo Park, CA (US)

(21) Appl. No.: 19/292,786

(22) Filed: Aug. 6, 2025

Related U.S. Application Data
(60) Provisional application No. 63/688,782, filed on Aug. 29, 2024.

(51) Int. Cl. H01S 5/14; H01S 5/026

(52) U.S. Cl. CPC H01S 5/141; H01S 5/026

(57) ABSTRACT

Various embodiments disclosed herein describe coupled cavity lasers, as well as photonic integrated circuits and photonic systems that incorporate coupled cavity lasers. A coupled cavity laser may define a plurality of laser cavities. Each laser cavity includes a corresponding gain medium of a plurality of gain mediums, a corresponding reflecting mirror of a plurality of reflecting mirrors, and a shared partial reflector. The components of a coupled cavity laser may be distributed across multiple photonic dies of a photonic integrated circuit. The photonic dies may include a plurality of gain media, a plurality of reflectors, and a shared partial reflector.

### CROSS-REFERENCE TO RELATED APPLICATIONS

This application claims the benefit under 35 U.S.C. § 119 (e) of U.S. Provisional Patent Application No. 63/688,782, filed Aug. 29, 2024, the contents of which are incorporated herein by reference as if fully disclosed herein.

### FIELD

This disclosure relates generally to photonic integrated circuits that include a coupled cavity laser. More particularly, a coupled cavity laser may include multiple laser cavities, each having a corresponding gain medium, that share a common partial reflector.

### BACKGROUND

Semiconductor lasers are commonly used as light sources in photonic systems. For example, one or more semiconductor light sources may be integrated into a photonics integrated circuit and may be operated to generate light that is used by other portions of the photonic integrated circuit for various applications, e.g., telecommunications, optical sensing, or the like. One example of a semiconductor laser is a cavity laser, in which a gain medium is positioned along an optical path between a pair of reflectors that form a resonant optical cavity. There may be limits, however, to the output power that may be produced by a cavity laser. Specifically, for a given configuration of the gain medium, increasing the length of the gain medium (and thereby the length of the resonant optical cavity) may increase the maximum output power of the cavity laser. This relationship is non-linear, and beyond a certain length the gain provided by the gain medium begins to saturate. Further increases to the length of the gain medium does not meaningfully increase the output power of the cavity laser. Depending on the application, a photonic system incorporating a light source may require the generation of light having an intensity beyond the capabilities of a single cavity laser. Accordingly, it may be desirable to provide light sources capable of providing increased optical power.

### SUMMARY

Described herein are coupled cavity lasers, as well as photonic integrated circuits and photonic systems incorporating coupled cavity lasers. Some variations are directed to a photonic system that includes a photonic integrated circuit. The photonic integrated circuit may include a first photonic die having a first gain medium, a second gain medium, a first reflecting mirror, and a second reflecting mirror. The photonic integrated circuit further includes a second photonic die having a shared partial reflector and a coupler optically connecting the first gain medium and the second gain medium to the shared partial reflector. The photonic integrated circuit includes a coupled cavity laser defining a first laser cavity and a second cavity, such that i) the first laser cavity includes the first reflecting mirror, the first gain medium, and the shared partial reflector, and ii) the second laser cavity includes the second reflecting mirror, the second gain medium, and the shared partial reflector.

In some variations, the coupler is a directional coupler. In other variations, the coupler is a multi-mode interference coupler. The shared partial reflector may be a distributed Bragg reflector. In some variations, the photonic integrated circuit includes a controllable phase shifter positioned along an optical path of the first laser cavity between the first reflecting mirror and the coupler. In some of these variations, the controllable phase shifter is positioned in the second photonic die.

In some variations, the photonic system includes a controller configured to control the coupled cavity laser to emit output light from the shared partial reflector. In some of these variations, the photonic system includes an optical monitor configured to receive a portion of the output light emitted by the coupled cavity laser and generate one or more feedback signals. In these variations, the controller may be configured to control the coupled cavity laser using the one or more feedback signals. In some variations, the second laser cavity includes a delay line positioned between the second reflecting mirror and the coupler. In some of these variations, the delay line is configured to provide a wavelength dependent periodic loss filter to the coupled cavity laser.

Other variations are directed to a photonic integrated circuit that includes a coupled cavity laser having a plurality of gain mediums, a plurality of reflecting mirrors, and a shared partial reflector. The coupled cavity laser defines a plurality of laser cavities, such that each laser cavity of the plurality of laser cavities includes: a corresponding gain medium of the plurality of gain mediums, a corresponding reflecting mirror of the plurality of reflecting mirrors, and the shared partial reflector.

In some variations, the photonic integrated circuit further includes a set of couplers optically connecting the plurality of gain mediums to the shared partial reflector. In some variations, the set of couplers includes a N×1 coupler, such as a 4×1 coupler. In other variations, the set of couplers includes a plurality of couplers. In some of these variations, the plurality of couplers includes: i) a first coupler including a first input, a second input, and a first output, ii) a second coupler including a first input, a second input, and a first output, and iii) a third coupler including a first input connected to the first output of the first coupler, a second input connected to the first output of the second coupler, and a first output. In some of these variations, the photonic integrated circuit includes a first controllable phase shifter positioned to control a corresponding phase of light in the first input of the first coupler. The photonic integrated circuit may further include a second controllable phase shifter positioned to control a corresponding phase of light in the second input of the second coupler, as well as a third controllable phase shifter positioned to control a corresponding phase of light in the first output of the second coupler.

Still other variations are directed to a photonic integrated circuit that includes a set of first photonic dies and a second photonic die. The set of first photonic dies includes a plurality of gain mediums and a plurality of reflecting mirrors, the second photonic die includes a shared partial reflector. The photonic integrated circuit includes a coupled cavity laser defining a plurality of laser cavities. Each laser cavity of the plurality of laser cavities includes: a corresponding gain medium of the plurality of gain mediums, a corresponding reflecting mirror of the plurality of reflecting mirrors, and the shared partial reflector.

In some variations, the photonic integrated circuit further includes a coupler optically connecting the plurality of gain mediums to the shared partial reflector. In some of these variations, the second photonic die includes the coupler. In some variations, the set of first photonic dies includes a first die, the plurality of gain mediums includes a first gain medium, and the first die of the set of first photonic dies includes the first gain medium. In some of these variations, the plurality of gain mediums includes a second gain medium and the first die of the set of first photonic dies includes the second gain medium. In other variations, the set of first photonic dies includes a second die, the plurality of gain mediums includes a second gain medium, and the second die of the set of first photonic dies includes the second gain medium.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a top view of a photonic integrated circuit that includes a single cavity laser.

FIGS. 2A and 2B show schematic views of photonic integrated circuits that include variations of coupled cavity lasers as described herein.

FIGS. 3A and 3B show top views of photonic integrated circuit that include variations of coupled cavity lasers as described herein.

FIGS. 4A and 4B show schematic views of photonic systems that include a coupled cavity laser and a controller.

FIG. 5 shows a schematic view of photonic integrated circuit that includes a variation of a coupled cavity laser having a delay line.

FIGS. 6A and 6B show schematic views of photonic integrated circuits that include variations of coupled cavity lasers as described herein.

It should be understood that the proportions and dimensions (either relative or absolute) of the various features and elements (and collections and subsettings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

Directional terminology, such as “top”, “bottom”, “upper”, “lower”, “front”, “back”, “over”, “under”, “above”, “below”, “left”, “right”, “vertical”, “horizontal”, etc. is used with reference to the orientation of some of the components in some of the figures described below, and is not intended to be limiting. Because components in various embodiments can be positioned in a number of different orientations, directional terminology is used for purposes of illustration to demonstrate the relative orientation between components of the systems and devices described herein. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to photonic systems that include a coupled cavity laser. Specifically, the coupled cavity laser includes a plurality of resonant optical cavities that share a shared partial reflector. Each resonant optical cavity (also referred to herein as a “laser cavity”) includes a corresponding optical path having a gain medium positioned between a corresponding reflecting mirror and the shared partial reflector. Each gain medium is operable to generate light. Accordingly, light may be generated and amplified along each of the plurality of laser cavities, and collectively this light may be emitted from the shared partial reflector. By utilizing multiple laser cavities, the coupled cavity laser may have increased optical power as compared to a cavity laser having a single laser cavity.

In some variations, a coupled cavity laser as described herein may be integrated into a photonic integrated circuit. In some of these variations, components of the coupled cavity lasers may be distributed between different photonic dies. These “hybrid” coupled cavity lasers may take advantage of the different materials and/or manufacturing processes used to form different photonic dies. For example, the gain mediums of the coupled cavity lasers may be formed as part of one or more photonic dies (e.g., a set of first photonic dies) and the shared partial reflector may be formed as part of a different photonic die (e.g., a second photonic die). In some instances, each photonic die of the set of first photonic dies is formed from one or more semiconductor materials and the second photonic die may be manufactured using silicon-on-insulator technology.

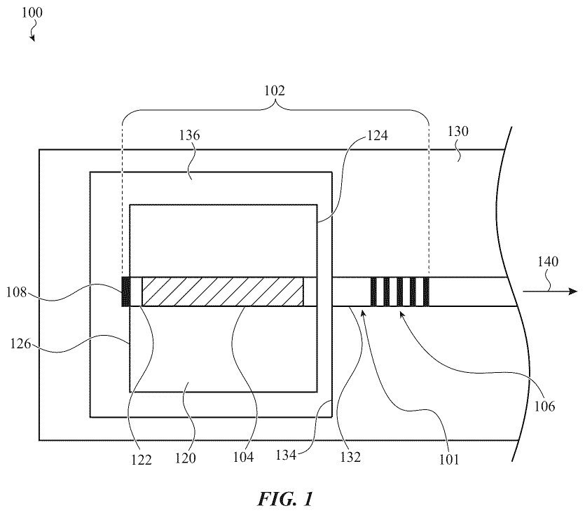

These and other embodiments are discussed with reference to FIGS. 1A-6B. However, those skilled in the art will readily appreciate that the detailed description given herein with respect to these figures is for explanatory purposes only and should not be construed as limiting.

FIG. 1 shows a top view of a photonic integrated circuit 100 that includes a cavity laser 101 having a single laser cavity 102. Specifically, the cavity laser 101 includes a gain medium 104, a partial reflector 106, and a reflecting mirror 108 that are positioned along a common optical path. Specifically, the optical path between the partial reflector 106 and the reflecting mirror 108 defines the laser cavity 102. The gain medium 104 may include one or more semiconductor materials (e.g., one or more quantum wells) and is operable to function as an optical amplifier. The cavity laser 101 may be configured to inject current into the gain medium 104 (e.g., using a set of electrodes, such as will be readily understood by someone of ordinary skill in the art), which will result in amplified spontaneous emission.

During operation of the cavity laser 101, photons generated by the gain medium 104 may traverse the laser cavity 102 between the partial reflector 106 and the reflecting mirror 108. Only light having certain wavelengths is able to form a standing wave that resonates within the laser cavity (also referred to as “resonant modes”). The resonant modes of the laser cavity 102 depend at least in part on the effective refractive index of the laser cavity 102, and depends at least in part on the length of the laser cavity 102. The partial reflector 106 may be configured to limit which resonant modes actually resonate during operation.

Specifically, the partial reflector 106 may have a bandwidth and may partially reflect light having wavelengths within the bandwidth. Conversely, the reflecting mirror 108 functions a total reflector to reflect light at least at wavelengths within the bandwidth of the partial reflector 106. For example, the reflecting mirror 108 may reflect light over a wider range of wavelengths that includes the bandwidth. Accordingly, only resonant modes that fall within the bandwidth of the partial reflector 106 will be able to reflect off of both the partial reflector 106 and the reflecting mirror 108 and constructively interfere within the laser cavity 102. Because the partial reflector 106 only partially reflects the resonant modes within the bandwidth of the partial reflector 106, some of the light at these resonant modes will pass through the partial reflector 106 as output light generated by the cavity laser 101. In some variations, the bandwidth of the partial reflector 106 is sufficiently narrow as to only reflect one resonant mode at any given time. In these instances, the partial reflector 106 effectively functions as a narrowband filter to suppress other resonant modes, which may allow the cavity laser 101 to output light having a single wavelength. It should be appreciated that the changing the effective refractive index of the laser cavity 102 (e.g., by heating a portion of the laser cavity) may change the resonant modes supported by the laser cavity 102, and thus the wavelength of light generated by the cavity laser 101 may be tuned within the bandwidth of the partial reflector 106.

In some variations, the gain medium 104 and the reflecting mirror 108 may be configured as a reflective semiconductor optical amplifier (“RSOA”). For example, the gain medium 104 may be formed as part of a first photonic die 120 of the photonic integrated circuit 100. The first photonic die 120 includes a waveguide 122 (also referred to as “first waveguide 122”) that extends between a first facet 124 and a second facet 126 of the first photonic die 120. The gain medium 104 may be formed along some or all of the first waveguide 122, such that the gain medium 104 is operable to amplify photons traveling through the first waveguide 122. In these instances, the reflecting mirror 108 may be positioned on the second facet 126 to help reflect light in the first waveguide 122 that reaches the second facet 126. For example, the reflecting mirror 108 may include a metal layer deposited on the second facet 126.

Conversely, light may enter and exit the waveguide 122 through the first facet 124. For example, the photonic integrated circuit 100 includes a second photonic die 130 that includes a second waveguide 132 that terminates at a first facet 134 of the second photonic die 130. The first photonic die 120 may be positioned relative to the second photonic die 130 such that the first facet 124 of the first photonic die 120 faces the first facet 134 of the second photonic die 130. For example, in the variation shown in FIG. 1, the second photonic die 130 is shaped to define a recess 136 that extends at least partially through the second photonic die 130, and the first photonic die 120 may be positioned such that a portion of the first photonic die 120 extends into the recess 136. In these instances, the first facet 134 of the second photonic die 130 may define a wall of the recess 136. In other instances, the first photonic die 120 and the second photonic die 130 may be positioned in a side-by-side arrangement. For example, the first photonic die 120 and the second photonic die 130 may be mounted to a common component (e.g., an interposer) such that the first facet 124 of the first photonic die 120 faces the first facet 134 of the second photonic die 130.

The first facet 124 of the first photonic die 120 and the first facet 134 of the second photonic die 130 may be positioned to align the first waveguide 122 and the second waveguide 132. In this way, light that exits the first photonic die 120 via the first waveguide 122 may enter the second photonic die 130 via the second waveguide 132, and vice versa. In some variations, the first facet 124 of the first photonic die 120 may be coated with an anti-reflective coating (not shown) that may reduce reflection as light enters or exits the first waveguide 122 at the first facet 124 of the first photonic die 120. Additionally or alternatively, the first facet 134 of the second photonic die 130 may be coated with an anti-reflective coating (not shown) that may reduce reflection as light enters or exits the second waveguide 132 at the first facet 134 of the second photonic die 120. In some variations, the photonic dies are positioned such that there is a gap between the first facet 124 of the first photonic die 120 and the first facet 134 of the second photonic die 130. In some of these variations, a fill material may be positioned to bridge the gap between the first facet 124 of the first photonic die 120 and the first facet 134 of the second photonic die 130. The fill material may be formed from a material that is transparent at the wavelengths generated by the cavity laser 101 and may help guide light between the first waveguide 122 and the second waveguide 132 and/or help shield the corresponding facets from particles or other contaminants.

Photons that are generated in the first photonic die 120 during operation of the gain medium 104 may travel from the first waveguide 122 to the second waveguide 132. The partial reflector 106 may be positioned along a portion of the second waveguide 132, such that light traveling through the second waveguide 132 will interact with the partial reflector 106 as described in more detail herein. Light that passes through the partial reflector 106 may travel along the second waveguide 132 as output light 140 generated by the cavity laser 101. In some variations, the partial reflector 106 may be a distributed Bragg reflector.

Positioning the gain medium 104 and the partial reflector 106 in different photon dies may allow these components to be formed using different materials and/or processing techniques. For example, the gain medium 104 may be formed from one or more semiconductor materials (e.g., one or more III-V semiconductor materials such as indium gallium arsenide or indium phosphide). In these instances, the first photonic die 120 may be include an epitaxial structure that includes various epitaxially-grown semiconductor layers that are used to define the gain medium 104 and the first waveguide 122.

Conversely, the second photonic die 130 may be formed from a different set of materials. For example, the second photonic die may be formed using silicon-on-insulator technology. Specifically, the second photonic die 130 may include a silicon substrate that supports a waveguide layer. The waveguide layer may be formed from silicon, silicon nitride, silica, or the like, and may be used to define the second waveguide 132. The waveguide layer may be separated from the silicon substrate by a cladding layer (e.g., silicon dioxide or the like), and the second photonic die 130 may include one or more additional cladding layers as may be desired to provide optical confinement to the second waveguide 132 (and/or other waveguides defined in the waveguide layer). When the partial reflector 106 is configured as a distributed Bragg reflector, the distributed Bragg reflector may be made from one or more materials that are consistent with silicon-on-insulator processing techniques. In one example, a distributed Bragg reflector may be formed from alternating regions of a waveguide material and a cladding material.

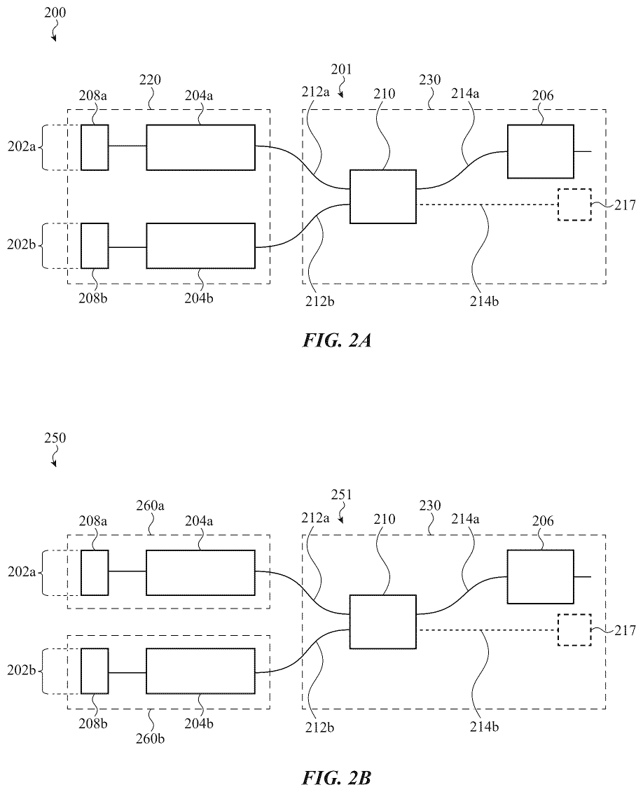

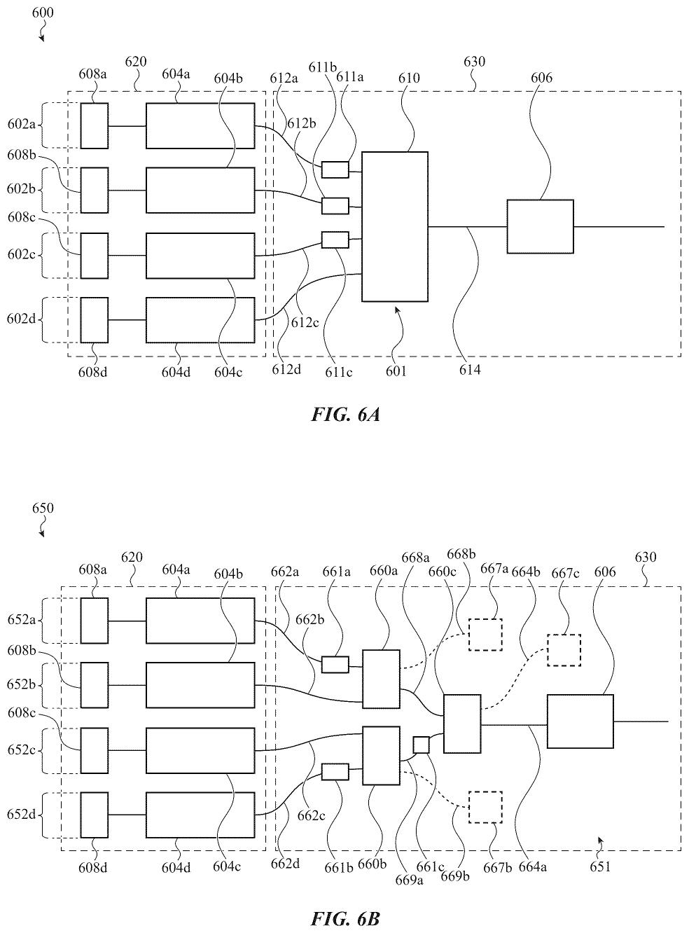

The coupled cavity lasers described herein include multiple laser cavities that utilize a shared partial reflector. Each laser cavity includes a corresponding gain medium that is operable to generate and amplify light within the laser cavity, a corresponding reflecting mirror, and the shared partial reflector. The multiple laser cavities may collectively generate the output light that is emitted by the coupled cavity laser. FIG. 2A shows a schematic view of a variation of a photonic integrated circuit 200 having a coupled cavity laser 201. The coupled cavity laser 201 defines a plurality of laser cavities 202a-202b, which in the variation shown in FIG. 2A includes a first laser cavity 202a and a second laser cavity 202b. In other variations, a couple coupled cavity laser may include three or more laser cavities, such as those described herein with respect to FIGS. 6A and 6B.

The coupled cavity laser 201 also includes a plurality of gain mediums 204a-204b and a plurality of reflecting mirrors 208a-208b, each of which may be configured in any manner as described herein with respect to the photonic integrated circuit 100 of FIG. 1. Each laser cavity of the plurality of laser cavities 202a-202b includes a corresponding optical path defined between a corresponding reflecting mirror of the plurality of reflecting mirrors 208a-208b and a shared partial reflector 206. Specifically, the first laser cavity 202a includes a first gain medium 204a of the plurality of gain mediums 204a-204b, where the first gain medium 204a is positioned along a first optical path defined between the shared partial reflector 206 and a first reflecting mirror 208a of the plurality of reflecting mirrors 208a-208b. Similarly, the second laser cavity 202b includes a second gain medium 204b of the plurality of gain mediums 204a-204b, where the second gain medium 204b is positioned along a second optical path defined between the shared partial reflector 206 and a second reflecting mirror 208b of the plurality of reflecting mirrors 208a-208b.

The coupled cavity laser 201 further includes a set of couplers that is configured to optically couple each of the plurality of gain mediums 204a-204b to the shared partial reflector 206. While shown in FIG. 2A as including a single coupler 210, the set of couplers may alternatively include a plurality of couplers such as described herein with respect to FIG. 6B. The set of couplers may include a plurality of inputs that correspond to the plurality of laser cavities 202a-202b. For example, in the variation shown in FIG. 2A, the coupler 210 includes a plurality of inputs 212a-212b that includes a first input 212a corresponding to the first laser cavity 202a and a second input 212b corresponding to the second laser cavity 202b.

The set of couplers further includes one or more outputs, such that light received by an input of the set of couplers may be routed to one or more of the outputs of the set of couplers. The shared partial reflector 206, which may be a distributed Bragg reflector, may be optically connected to an output of the set of couplers, such that the shared partial reflector 206 may receive light from any of the plurality of gain mediums 204a-204b. For example, in the variations shown in FIG. 2A, the coupler 210 includes a set of outputs 214a-214b. The set of outputs 214a-214b includes at least a first output 214a that is optically coupled to the shared partial reflector 206. For example, the coupler 210 may be a 2×1 coupler such as a multimode interference (MMI) coupler, a y-splitter, or the like. In other variations, the set of outputs 214a-214b may further include a second output 214b. In these variations, the coupler may be a 2×2 coupler, such as a directional coupler or the like.

In variations where the coupler 210 includes a second output 214b, the second output 214b may be configured as a dump port, such that light that is coupled to the second output 214b is absorbed or otherwise removed from the photonic integrated circuit. This may reduce the likelihood that light reaching the second output 214b undesirably scatters or couples into other portions of the photonic integrated circuit 200. In some instances, the second output 214b may include or otherwise be connected to a light absorbing region 217. The light absorbing region 217, which may be formed as a doped region of a waveguide or another light absorbing material, may function to absorb light that is coupled into the second output 214b. In instances where the light absorbing region 217 includes a doped region of a waveguide, a width of the doped region of the waveguide may be tapered to reduce the likelihood of back reflections from the light absorbing region 217. In other variations, the second output 214b may be connected to a component, such as a photodetector, that is configured to measure the amount of light that is carried in the second output 214b. In these instances, information about the amount of light coupled into the second output 214b may be used in controlling the coupled cavity laser 201.

Because the first output 214a of the coupler 210 is optically coupled to each of the plurality of gain mediums 204a-204b, the first output 214a of the coupler 210 forms a part of each of the plurality of laser cavities 202a-202b. For example, the optical path that forms the first laser cavity 202a includes the first input 212a and the first output 214a of the coupler 210, whereas the optical path that forms the second laser cavity 202b includes the second input 212b and the first output 214a of the coupler 210.

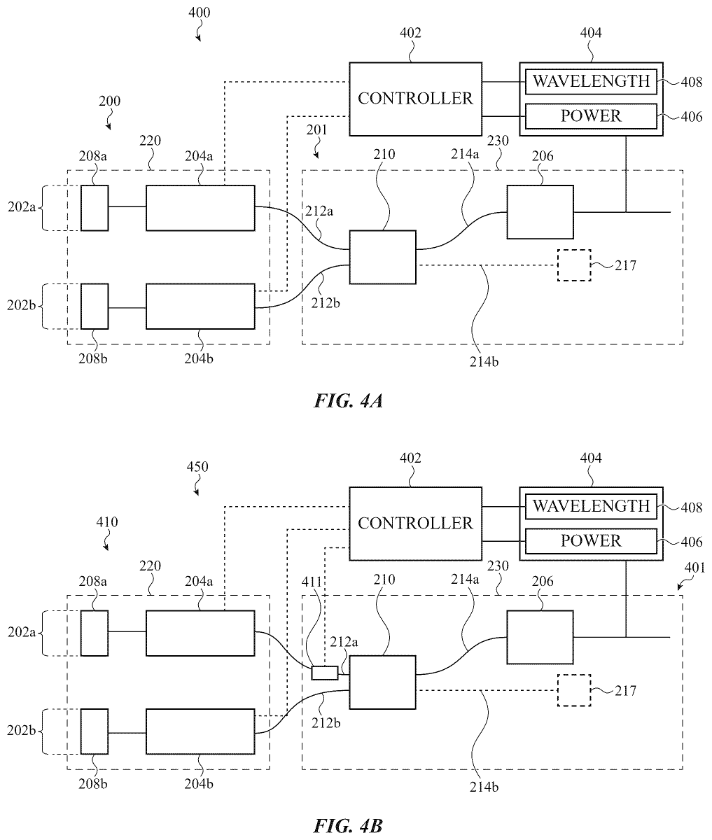

During operation of the coupled cavity laser 201, the plurality of gain mediums 204a-204b are collectively operated to generate and amplify photons via amplified spontaneous emission. Depending on the operation of the individual gain mediums, each laser cavity of the plurality of laser cavities 202a-202b will be able to generate a corresponding resonant mode, and the coupled cavity laser 201 will emit output light via the shared partial reflector 206. The operation of the individual laser cavities of the plurality of laser cavities 202a-202b may be controlled to alter the relative effective refractive index of the plurality of laser cavities 202a-202b, which in turn may impact how much light is outputted by the coupled cavity laser 201. To maximize the output power of the coupled cavity laser 201 it may be desirable to operate the plurality of laser cavities 202a-202b such that photons reaching the shared partial reflector 206 are in phase, regardless of which optical path that laser cavity traverses within the coupled cavity laser 201. In this way, the optical fields of the plurality of laser cavities 202a-202b will add in phase to increase the output power of the coupled cavity laser 201. Examples of techniques for controlling a coupled cavity laser, such as coupled cavity laser 201 of FIG. 2A, are described herein with respect to FIGS. 4A and 4B.

The coupled cavity laser 201 may be configured as a hybrid coupled cavity laser, such that the plurality of gain mediums 204a-204b are formed as part of a set of first photonic dies and the shared partial reflector 206 is formed as part of a second photonic die. For example, in the variation of the photonic integrated circuit 200 shown in FIG. 2A, the photonic integrated circuit 200 includes a single first photonic die 220 and a second photonic die 230. In these variations, the plurality of gain mediums 204a-204b and the plurality of reflecting mirrors 208a-208b may each be incorporated into the first photonic die 220, and the shared partial reflector 206 may be incorporated into the second photonic die 230. In the variation shown in FIG. 2A, the coupler 210 is also incorporated into the second photonic die 230.

In other variations, some or all of the plurality of gain mediums 204a-204b may be incorporated into different photonic dies. For example, FIG. 2B shows a variation of a photonic integrated circuit 250 that is configured and labeled the same as the photonic integrated circuit 200 of FIG. 2A except that the first photonic die 220 is replaced with a plurality of first photonic dies 260a-260b. The photonic integrated circuit 250 includes a coupled cavity laser 251 that is configured and labeled the same as the coupled cavity laser 201 of FIG. 2A, except that the first gain medium 204a and the first reflecting mirror 208a are incorporated into a first die 260a of the plurality of first photonic dies 260a-260b and the second gain medium 204b and the second reflecting mirror 208b are incorporated into a second die 260b of the plurality of first photonic dies 260a-260b. Accordingly, the first optical path of first laser cavity 202a traverses the first die 260a of the plurality of first photonic dies 260a-260b and the second photonic die 230, whereas the second optical path of second laser cavity 202b traverses the second die 260b of the plurality of first photonic dies 260a-260b and the second photonic die 230.

In this way, photons generated by the first gain medium 204a will travel from the first die 260a of the plurality of first photonic dies 260a-260b to the second photonic die 230. Similarly, photons generated by the second gain medium 204b will travel from the second die 260b of the plurality of first photonic dies 260a-260b to the second photonic die 230. Conversely, photons that reflect off the shared partial reflector 206 will pass through coupler 210 via the first output 214a, and will be routed to the plurality of first photonic dies 260a-260b via the plurality of inputs 212a-212b.

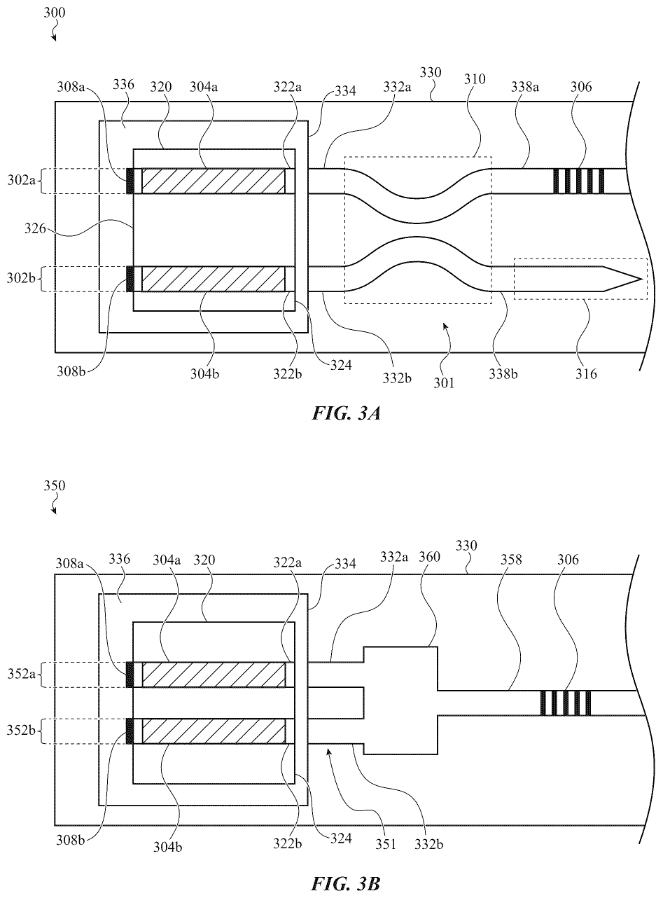

FIGS. 3A and 3B show examples of coupled cavity lasers that can be configured as described herein with respect to the coupled cavity lasers 201, 251 of FIGS. 2A and 2B. For example, FIG. 3A shows one variation of photonic integrated circuit 300 that includes a first variation of a coupled cavity laser 301. The coupled cavity laser 301 includes a plurality of gain mediums 304a-304b, a shared partial reflector 306, a plurality of reflecting mirrors 308a-308b, and a coupler 310. In the variation shown in FIG. 3A, the coupler 310 is configured as a 2×2 couplers, specifically a directional coupler having two inputs and two outputs. In some variations, the shared partial reflector 306 is a distributed Bragg reflector.

In the variation shown in FIG. 3A, the photonic integrated circuit 300 includes a first photonic die 320 and a second photonic die 330. The first photonic die 320 includes a pair of waveguides 322a-322b that includes a first waveguide 322a (also referred to as “first gain waveguide 322a”) and a second waveguide 322b (also referred to as “second gain waveguide 322b”). The first gain waveguide 322a and the second gain waveguide 322b that extends between a first facet 324 and a second facet 326 of the first photonic die 320. The plurality of gain mediums 304a-304b may include a first gain medium 304a and a second gain medium 304b, such that the first gain medium 304a is formed along some or all of the first gain waveguide 322a and the second gain medium 304b is formed along some or all of the second gain waveguide 322b. In this way, the first gain medium 304a is operable to amplify photons traveling through the first gain waveguide 322a and the second gain medium 304b is operable to amplify photons traveling through the second gain waveguide 322b.

Similarly, the plurality of reflecting mirrors 308a-308b may include a first reflecting mirror 308a and a second reflecting mirror 308b, each of which may be positioned on the second facet 326 of the first photonic die 320. Specifically, the first reflecting mirror 308a is positioned to reflect light in the first gain waveguide 322a that reaches the second facet 326 and the second reflecting mirror 308b is positioned to reflect light in the second gain waveguide 322b that reaches the second facet 326. In some variations, such as shown in FIG. 3A, the first reflecting mirror 308a and the second reflecting mirror 308b are formed as separate components. For example, the first reflecting mirror 308a may be formed from a first metal layer deposited on the second facet 326 and the second reflecting mirror 308b be formed from as second metal layer, separate from the first metal layer, that is also deposited on the second facet 326. In other variations, the first reflecting mirror 308a and the second reflecting mirror 308b may be different regions of a common component. For example, a single metal layer may be deposited on the second facet 326 and sized such that it overlaps both the first gain waveguide 322a and the second gain waveguide 322b. In these instances, a first portion of the metal layer overlapping the first gain waveguide 322a may form the first reflecting mirror 308a and a second portion of the metal layer overlapping the second gain waveguide 322b may form the second reflecting mirror 308a.

The first photonic die 320 may be positioned relative to the second photonic die 330 such that light may travel between the first facet 324 of the first photonic die 320 and a first facet 334 of the second photonic die. Specifically, the first photonic die 320 may be positioned relative to the second photonic die 330 such that the first facet 324 of the first photonic die 320 faces the first facet 334 of the second photonic die 330, such as described herein with respect to the photonic integrated circuit 100 of FIG. 1. For example, the second photonic die 330 is shaped to define a recess 336 that extends at least partially through the second photonic die 330, and the first photonic die 320 may be positioned such that a portion of the first photonic die 320 extends into the recess 336.

The second photonic die 330 includes a pair of waveguides 332a-332a that terminate at the first facet 334. The pair of waveguides 332a-332b includes a first waveguide 332a (referred to herein as “first input waveguide 332a”) and a second waveguide 332a (referred to herein as “second input waveguide 332b”). The first input waveguide 332a is aligned with the first gain waveguide 322a, such that light exiting the first photonic die 320 via the first gain waveguide 322a enters the second photonic die 330 via the first input waveguide 332a, or vice versa. Similarly, the second input waveguide 332b is aligned with the second gain waveguide 322b, such that light exiting the first photonic die 320 via the first gain waveguide 322a enters the second photonic die 330 via the first input waveguide 332a, or vice versa.

While the first input waveguide 332a and the second input waveguide 332b are shown in FIG. 3A as terminating at a common facet of the second photonic die 330 (e.g., the first facet 334 of the second photonic die 330), in other variations the first input waveguide 332a and the second input waveguide 332b may terminate at different corresponding facets of the second photonic die 330. Additionally or alternatively, corresponding ends of the first gain waveguide 322a and the second gain waveguide 322b that are aligned with the first input waveguide 332a and the second input waveguide 332b may be positioned to terminate at different corresponding facets of the first photonic die 320. In still other variations, the first gain waveguide 322a and the second gain waveguide 322a may be incorporated into different photonic dies. For example, the first gain waveguide 322a may be incorporated into a first die of a plurality of first photonic dies, and the second gain waveguide 322b may be incorporated into as second die of the plurality of first photonic dies, such as described herein with respect to FIG. 2B. In variations where the second photonic die 330 defines a recess 336 extending at least partially through the second photonic die 330, each of the plurality of first photonic dies may be positioned at least partially inside of the recess 336.

The first input waveguide 332a and the second input waveguide 332b may form respective first and second inputs of the coupler 310. The second photonic die 330 may further include a second pair of waveguides 338a-338b that includes a first waveguide 338a (referred to herein as “first output waveguide 338a”) and a second waveguide 338b (referred to herein as “second output waveguide 338b”). The first output waveguide 338a and the second output waveguide 338b form respective first and second outputs of the coupler 310. The shared partial reflector 306 is positioned along the first output waveguide 338a, such that light exiting the coupler 310 along the first output waveguide 338a will interact with the partial reflector 306.

In some variations, the second output waveguide 338b may be configured to function as a dump port, such as described herein with respect to the photonic integrated circuit 200 of FIG. 2A. In some of these variations, the second photonic die 330 may be configured that light exiting the coupler 310 along the second output waveguide 338b will be absorbed by the second photonic die 330. For example, the second output waveguide 338b may include a doped region 316 that is doped (e.g., is p-doped) to increase the absorption of light traveling through the second output waveguide 338b. In other variations, the second output waveguide 338b may be optically connected to a component, such as a photodetector, that is configured to measure the amount of light that is carried in the second output waveguide 338b.

Overall, the coupled cavity laser 301 defines a plurality of laser cavities 302a-302b that includes a first laser cavity 302a and a second laser cavity 302b. The first laser cavity 302a includes a first optical path defined between the first reflecting mirror 308a and the shared partial reflector 306, and includes the first gain waveguide 322a, the first input waveguide 332a, the coupler 310, and the first output waveguide 338a. The second laser cavity 302b includes a second optical path defined between the second reflecting mirror 308b and the shared partial reflector 306, and includes the second gain waveguide 322b, the second input waveguide 332b, the coupler 310, and the first output waveguide 338a.

During operation of the coupled cavity laser 301, light generated by the plurality of gain mediums 304a-304b will travel along the plurality of laser cavities 302a-302b, and output light having a resonant mode will be emitted from the coupled cavity laser 301 through the shared partial reflector 306 along the first output waveguide 338a. As light travels within the coupled cavity laser, it is possible for given photon that makes multiple round trips through the coupled cavity laser 301 to traverse both laser cavities as it reflects off of the partial reflector 306 and passes through the coupler 310 via the first output waveguide 338a. As light enters the coupler 310 via the first input waveguide 332a and the second input waveguide 332b, light is coupled by the coupler 310 into first output waveguide 338a and/or the second output waveguide 338b. The relative amount that is coupled into the first output waveguide 338a versus the second output waveguide 338b depends at least in part on i) the relative intensity of light entering the coupler 310 from the first input waveguide 332a and the second input waveguide 332b, ii) the relative phase of light entering the coupler 310 from the first input waveguide 332a and the second input waveguide 332b, and iii) the splitting ratio of the coupler 310. For example, if the coupler 310 has a 50-50 splitting ratio, and the light in the first input waveguide 332a and the second input waveguide 332b have i) the same intensity and ii) are π/2 out of phase, light may be coupled entirely into the first output waveguide 338a. To the extent that one of these conditions is changed (e.g., due to temperature fluctuations in the photonic integrated circuit 300), some of the light may instead be coupled to the second output waveguide 338b. To improve the output power of the coupled cavity laser 301, the coupled cavity laser 301 may be operated in a manner designed to minimize the amount of light that is coupled into the second output waveguide 338b, such as described herein with respect to FIGS. 4A and 4B.

FIG. 3B shows another variation of photonic integrated circuit 350 that includes a second variation of a coupled cavity laser 351. The photonic integrated circuit 350 and the coupled cavity laser 351 are configured and labeled the same as the photonic integrated circuit 300 and coupled cavity laser 301 of FIG. 3A, except that the coupler 310 has been replaced by a coupler 360 and the first output waveguide 338a and the second output waveguide 338b have been replaced by a single output waveguide 358 in the second photonic die 330. In this variation, the coupler 360 is configured as 2×1 coupler, specifically a 2×1 MMI coupler, having two inputs and a single output. In these variations, the first input waveguide 332a and the second input waveguide 332b form respective first and second inputs of the coupler 360, and the output waveguide 358 forms the output of the coupler 360.

The shared partial reflector 306 may be positioned along the output waveguide 358 and may be shared by each of a plurality of laser cavities 352a-352b of the coupled cavity laser 351. Specifically, the plurality of laser cavities 352a-352b includes a first laser cavity 352a and a second laser cavity 352b. The first laser cavity 352a includes a first optical path defined between the first reflecting mirror 308a and the shared partial reflector 306, and includes the first gain waveguide 322a, the first input waveguide 332a, the coupler 360, and the output waveguide 358. The second laser cavity 352b includes a second optical path defined between the second reflecting mirror 308b and the shared partial reflector 306, and includes the second gain waveguide 322b, the second input waveguide 332b, the coupler 360, and the output waveguide 358.

During operation of the coupled cavity laser 351, light generated by the plurality of gain mediums 304a-304b will travel along the plurality of laser cavities 352a-352b and output light having a resonant mode will be emitted from the coupled cavity laser 351 through the shared partial reflector 306 along the output waveguide 358. As light enters the coupler 360 via the first input waveguide 332a and the second input waveguide 332b, at least a portion of the light is coupled by the coupler 360 into the output waveguide 358. When the coupler 360 is a MMI coupler, the light from the first input waveguide 332a and the second input waveguide 332b may be added at the output waveguide 358 if they are in phase. In these instances, the operation of the coupled cavity laser 351 may be controlled to minimize the phase difference of light entering the coupler 360 between the first input waveguide 332a and the second input waveguide 332b. Whereas losses associated with the coupler 310 during the operation of the coupled cavity laser 301 of FIG. 3A will be routed to the second output waveguide 338b, losses associated with the coupler 360 (e.g., resulting from phase mismatch between the inputs of the coupler 360) during the operation of the coupled cavity laser 351 may be coupled into other portions of the second photonic die 330 as stray light. Accordingly, it may be desirable to configure the second photonic die 330 with additional light absorbing regions (not shown) positioned to capture and absorb this stray light.

A range of different control techniques may be used to control the operation of the coupled cavity lasers as described herein. For example, in some variations, the injection current used to operate the plurality of gain mediums may be selectively varied to control the output power and wavelength of output light emitted by the coupled cavity laser. For example, FIG. 4A shows a first variation of a photonic system 400 that includes the photonic integrated circuit 200 of FIG. 2A. The photonic system 400 includes a controller 402 that is configured to control the operation of the coupled cavity laser 201. The controller 402 may include any combination of software, hardware, and firmware as needed to control operation of the coupled cavity laser 201, including, for example, one or more processors and/or application-specific integrated circuits (ASICs). While the controller 402 is shown in FIG. 4A as controlling the operation of the coupled cavity laser 201 of FIG. 2A, it should be appreciated the principles described herein may be applied to any of the coupled cavity lasers described herein.

The controller 402 may control the operation of each of the plurality of gain mediums 204a-204b. Specifically, the controller 402 may be configured to drive a corresponding drive current through each gain medium of the plurality of gain mediums 204a-204b to control that gain medium. While operating a given gain medium of the plurality of gain mediums 204a-204b, there is a relationship between the corresponding drive current and the temperature of the gain medium. Accordingly, the drive current may heat the gain medium and thereby change the effective refractive index of the laser cavity that incorporates the gain medium. Specifically, the controller 402 may control the first gain medium 204a using a first drive current and may control the second gain medium 204b using a second drive current. Changes to the first drive current may change an effective refractive index of the first laser cavity 202a, whereas changes to the second drive current may change an effective refractive of the second laser cavity 202b.

The first and second drive currents may be selected to adjust the output power and wavelength of light emitted by the coupled cavity laser 201. Adjusting the first drive current relative to the second drive current may change the relative phase of light entering the coupler 210 through the plurality of inputs 212a-212b. Changing the relative phase of light entering the coupler may control the amount of light that is coupled into the first output 214a of the coupler 210, which may thereby control the output power of light emitted by the coupled cavity laser 201. Similarly, adjusting the first drive current and/or second drive current may change the average effective index of the plurality of laser cavities 202a-202b, which may control the wavelength of light emitted by the coupled cavity laser 201. Accordingly, the first drive current and second drive current may be selected to achieve both i) a particular difference between the effective refractive indices between the laser cavities 202a-202b to provide a particular output power of light emitted by the coupled cavity laser 201, and ii) a particular average effective index of the laser cavities 202a-202b to provide a particular wavelength of light emitted by the coupled cavity laser 201.

In some variations, the controller may receive one or more feedback signals in controlling the coupled cavity laser 201. Specifically, the photonic system 400 may include a optical monitor 404 that is configured to receive a portion of the light emitted by the coupled cavity laser 201. The optical monitor 404 is configured to output one or more feedback signals that vary with a corresponding property of the light emitted by the coupled cavity laser 201. The controller 402 may receive the one or more feedback signals from the optical monitor 404 and may use the feedback signals to control the operation of the coupled cavity laser 201.

In some variations, the optical monitor 404 includes a power monitor 406 that is configured to generate one or more feedback signals (referred to herein as “power feedback signals”) that vary with changes in the intensity of the light emitted by the coupled cavity laser 201. For example, in some variations the power monitor 406 includes a set of detector elements (e.g., a single detector element or multiple detector elements), each of which is positioned to measure a corresponding portion of the light emitted by the coupled cavity laser 201. The amount of light received by the set of detector elements may vary with the intensity of the light emitted by the coupled cavity laser 201, and thus each detector element of the set of detector elements generates a corresponding power feedback signal.

The controller 402 may receive one or more power feedback signals from the power monitor 406 and may control the operation of the coupled cavity laser 201 based at least in part on the received power feedback signal(s). In some variations, the controller 402 may control the coupled cavity laser 201 so that the coupled cavity laser 201 emits light having a target output power. In these variations, the controller 402 may use the one or more power feedback signals to maintain the output power emitted by the coupled cavity laser 201 at the target output power. As the output power of light emitted by the coupled cavity laser 201 deviates from the target output power, the one or more power feedback signals will change accordingly. The controller 402 may detect these changes, and may adjust the operation of the coupled cavity laser 201 (e.g., by adjusting one or more of the drive currents used to control the plurality of gain mediums 204a-204b) to return the emitted light to the target output power.

Additionally or alternatively, the optical monitor 404 includes a wavelength monitor 408 that is configured to generate one or more feedback signals (referred to herein as “wavelength feedback signals”) that vary with changes in the wavelength of the light emitted by the coupled cavity laser 201. For example, in some variations the wavelength monitor 408 includes a set of interferometric components (e.g., a single interferometric component or multiple interferometric component), such as Mach-Zehnder interferometers, multi-mode interferometers, or the like, each of which is positioned to received a corresponding portion of the light emitted by the coupled cavity laser 201 and generate a corresponding output signal. Each output signal may have an intensity that varies as a function of wavelength, and the wavelength monitor 408 may include a corresponding set of detector elements that is configured to measure the output signal(s) generated by the set of interferometric components. Accordingly, the amount of light received by the set of detector elements may vary with the wavelength of the light emitted by the coupled cavity laser 201, and thus each detector element of the set of detector elements generates a corresponding wavelength feedback signal.

The controller 402 may receive one or more wavelength feedback signals from the wavelength monitor 408, and may control the operation of the coupled cavity laser 201 based at least in part on the received wavelength feedback signal(s). In some variations, the controller 402 may control the coupled cavity laser 201 so that the coupled cavity laser 201 emits light having a target wavelength. In these variations, the controller 402 may use the one or more wavelength feedback signals to maintain the wavelength of light emitted by the coupled cavity laser 201 at the target wavelength. As the wavelength of light emitted by the coupled cavity laser 201 deviates from the target wavelength, the one or more wavelength feedback signals will change accordingly. The controller 402 may detect these changes, and may adjust the operation of the coupled cavity laser 201 (e.g., by adjusting one or more of the drive currents used to control the plurality of gain mediums 204a-204b) to return the emitted light to the target wavelength. It should be appreciated that, in some instances, the controller 402 may control the operation of the coupled cavity laser 201 such that the coupled cavity laser 201 emits light having both a target wavelength and a target output power.

In the variation of the photonic system 400 shown in FIG. 4A, the output power and the wavelength of light emitted by the coupled cavity laser can be controlled solely by changing some or all of the drive currents used to operate the plurality of gain mediums 204a-204b. In these instances, however, changing the relative drive currents used to operate the plurality of gain mediums 204a-204b may change the relative gain provided by each of the plurality of gain mediums 204a-204b. This may cause power imbalances of light received at the inputs 212a-212b of the coupler 210, which may increase losses associated with the coupler 210 (and thereby the coupled cavity laser 201). Accordingly, it may be desirable to control the coupled cavity laser 201 while reducing losses associated with the coupler 210.

In some variations, the coupled cavity laser may include a set of controllable phase shifters, each of which is operable to change the relative phase of light entering a corresponding coupler of the coupled cavity laser. Overall, the set of controllable phase shifters may be operable to change the relative refractive indices of the plurality of laser cavities. For example, FIG. 4B shows another variation of a photonic system 450, which may be configured in any manner described with respect to the photonic system 400 of FIG. 4, except that the photonic integrated circuit 200 has been replaced with photonic integrated circuit 410 having a coupled cavity laser 401. The photonic integrated circuit 410 and the coupled cavity laser 401 may be configured the same as the photonic integrated circuit 200 and coupled cavity laser 201, except that the coupled cavity laser 401 includes a controllable phase shifter 411 positioned along the first optical path of the first laser cavity 202a between the first reflecting mirror 208a and the coupler 210. The controllable phase shifter 411 is operable to change a phase of light passing through a portion of the first optical path, which may change the relative phase of light entering the coupler 210 through the plurality of inputs 212a-212b. When the coupled cavity laser 401 is a hybrid coupled cavity laser, the controllable phase shifter 411 may be part of the first photonic die 220 (e.g., positioned in the first photonic die 220 to controllably change the phase of light passing through a waveguide of the first photonic die 220, such as the first gain waveguide 322a of FIGS. 3A and 3B) or part of the second photonic die 230 (e.g., positioned in the second photonic die 230 to controllably change the phase of light passing through a waveguide of the second photonic die 230, such as the first input waveguide 332a of FIGS. 3A and 3B).

Examples of suitable controllable phase shifters include, for example, electrooptic phase shifters that change the refractive index of a portion of a waveguide using an applied electric field (e.g., via carrier injection), thermo-optic phase shifters that change the refractive index of a portion of a waveguide by changing its temperature, and optomechanical phase shifters (e.g., a MEMs phase shifter) where a moveable structure (e.g., a suspended waveguide) is moved to change an amount evanescent coupling with the waveguide. While a single phase shifter 411 is shown in FIG. 411, it should be appreciated that the coupled cavity laser 401 may include an additional phase shifter (not shown) positioned to change a corresponding phase of light passing through a portion of the second optical path. In these instances, the phase shifter 411 and the additional phase shifter may be collectively operated to change the relative phase of light entering the coupler 210 through the plurality of inputs 212a-212b, which may provide the coupled cavity laser 401 with additional flexibility in controlling the relative phase.

In these variations, the controller 402 may further control the controllable phase shifter 411 as part of operation of the coupled cavity laser 401. Specifically, the controller 402 may drive each of the plurality of gain mediums 204a-204b with a corresponding drive current, and may operate the controllable phase shifter 411 to provide a target phase shift. Collectively, the drive currents and the target phase shift will control the output power and the wavelength of light emitted by the coupled cavity laser 401. In instances where the photonic system 450 includes the optical monitor 404, the controller 402 may select the drive currents and the target phase shift using one or more feedback signals from the optical monitor 404 (e.g., one or more power feedback signals and/or wavelength feedback signals). Because the controllable phase shifter 411 may be controlled to change the relative phase of light entering the coupler 210, the plurality gain mediums 204a-204b may be controlled to reduce the power imbalance of light received by the inputs 212a-212b of the coupler 210. Accordingly, the controllable phase shifter 411 may help reduce losses associated with operating the coupled cavity laser 401.

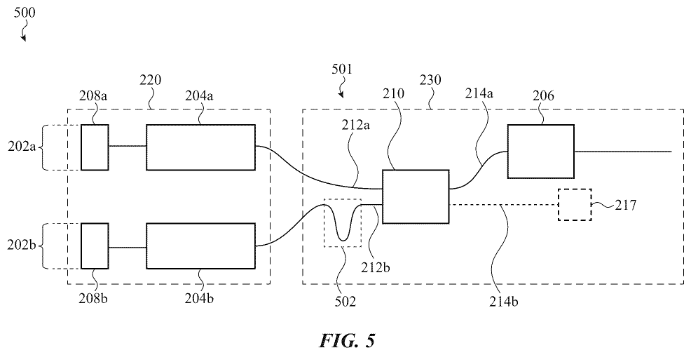

Depending on the configuration of the coupled cavity lasers described herein, the laser cavities defined by a coupled cavity laser may have corresponding optical paths having a common length or different path lengths. For example, in some variations, a laser cavity of a coupled cavity laser may include a delay line, such that the laser cavity has a different length than one or more other laser cavities of the coupled cavity laser. For example, FIG. 5 shows one variation of photonic integrated circuit 500 as described herein that includes a coupled cavity laser 501. The photonic integrated circuit 500 and the coupled cavity laser 501 are configured and labeled the same as the photonic integrated circuit 200 and coupled cavity laser 201 of FIG. 2A, except that the second laser cavity 202b includes a delay line 502 positioned between second reflecting mirror 208b and the coupler 210. The delay line 502 increases the length of the second laser cavity 202b relative to the first laser cavity 202a.

In some variations, the length of the delay line 502 may be selected to provide a predetermined phase difference between light entering the coupler 210 via the first input 212a and the second input 212b. For example, in variations the coupler 210 includes a directional coupler (such as the coupler 310 of FIG. 3A), the length of the delay line 502 may be selected such that light entering the coupler 210 via the second input 212b has a π/2 phase shift relative to light entering the coupler 210 via the first input 212a. This passive phase shift may simplify operation of the coupled cavity laser 501, as smaller adjustments to the drive currents (and/or phase shifts provided by a controllable phase shifter, such as controllable phase shifter 411) may be required to achieve a target output power of the coupled cavity laser 501. In variations in which the coupled cavity laser 501 includes a controllable phase shifter, such as controllable phase shifter 411 of the coupled cavity laser 401 of FIG. 4B, the controllable phase shifter and the delay line 502 may be part of the same laser cavity or may be part of different laser cavities.

In some variations, the length of the delay line 502 may be selected such that the delay line 502 functions as a wavelength dependent periodic loss filter. If the length of the delay line 502 is sufficiently long (e.g., on the order multiple microns), light traveling within the plurality of laser cavities 202a-202b will experience a wavelength dependent loss according to a periodic function having a bandwidth and periodicity. The bandwidth and periodicity of the loss filter may depend on the length of the delay line 502. By adding a periodic loss filter to the coupled cavity laser 501, the delay line 502 may increase the mode hop free frequency range of the coupled cavity laser 501. In other words, the periodic loss filter narrows the bandwidth of the shared partial reflector 206 and reduces the likelihood of mode hopping during operation of the coupled cavity laser 501. In variations in which the delay line 502 is configured to provide a wavelength dependent periodic loss filter to the coupled cavity laser 501, the coupled cavity laser 501 may be operated (e.g., by adjusting the drive currents used to operate the plurality of gain mediums 204a-204b and/or phase shifts provided by a controllable phase shifter) to tune the periodic loss filter. For example, the coupled cavity laser 501 may be operated to align a peak of the wavelength dependent periodic loss filter with the peak transmission of the shared partial reflector 206. In variations where the coupled cavity laser 501 includes a delay line, the delay line may be positioned in the first photonic die 220 (e.g., as part of a waveguide of the first photonic die, such as the second gain waveguide 322b of FIGS. 3A and 3B), may be positioned in the second photonic die 230 (e.g., as part of a waveguide of the second photonic die, such as the second input waveguide 332b of FIGS. 3A and 3B), or may be distributed between the first photonic die 220 and the second photonic die 230 (e.g., a first portion of the delay line 502 may be formed as part of a waveguide of the first photonic die and a second portion of the delay line 502 may be formed as part of a waveguide in the second photonic die 230).

While the variations of the coupled cavity lasers described with respect to FIGS. 2A-5 are each shown as having two laser cavities, it should be appreciated that any of these coupled cavity lasers may be configured with three or more laser cavities. For example, FIGS. 6A and 6B show variations of coupled cavity lasers having more than two laser cavities. FIG. 6A shows a schematic view of a variation of a photonic integrated circuit 600 having a coupled cavity laser 601. The coupled cavity laser 601 includes a plurality of laser cavities 602a-602d, which in the variation shown in FIG. 6A includes a first laser cavity 602a, a second laser cavity 602b, a third laser cavity 602c, and a fourth laser cavity 602d. It should be appreciated that the plurality of laser cavities may alternatively include only three laser cavities or may include five or more laser cavities as may be desired.

The coupled cavity laser 601 also includes a plurality of gain mediums 604a-604d and a plurality of reflecting mirrors 608a-608d, each of which may be configured in any manner as described herein with respect to the photonic integrated circuit 200 of FIG. 2A. Each laser cavity of the plurality of laser cavities 602a-602d includes a corresponding optical path defined between a corresponding reflecting mirror of the plurality of reflecting mirrors 608a-608d and a shared partial reflector 606. Specifically, the first laser cavity 602a includes a first gain medium 604a of the plurality of gain mediums 604a-604d, where the first gain medium 604a is positioned along a first optical path defined between the shared partial reflector 606 and a first reflecting mirror 608a of the plurality of reflecting mirrors 608a-608d. The second laser cavity 602b includes a second gain medium 604b of the plurality of gain mediums 604a-604d, where the second gain medium 604b is positioned along a second optical path defined between the shared partial reflector 606 and a second reflecting mirror 608b of the plurality of reflecting mirrors 608a-608d. The third laser cavity 602c includes a third gain medium 604c of the plurality of gain mediums 604a-604d, where the third gain medium 604c is positioned along a third optical path defined between the shared partial reflector 606 and a third reflecting mirror 608c of the plurality of reflecting mirrors 608a-608d. The fourth laser cavity 602d includes a fourth gain medium 604d of the plurality of gain mediums 604a-604d, where the fourth gain medium 604d is positioned along a fourth optical path defined between the shared partial reflector 606 and a fourth reflecting mirror 608d of the plurality of reflecting mirrors 608a-608d.

The coupled cavity laser 601 further includes a set of couplers that is configured to optically couple each of the plurality of gain mediums 604a-604d to the shared partial reflector 606. In some variations, the set of couplers includes a single N×1 coupler 610 having N inputs and one output, where N is the number of laser cavities 602a-602d defined by the coupled cavity laser 601. For example, in the variation shown in FIG. 6A, the coupler 610 includes a 4×1 coupler having four inputs 612a-612d and an output 614. The coupler 610 may be any suitable N×1 coupler, such as a N×1 MMI coupler.

The coupler 610 may optically couple the first output 614 of the coupler 610 to each of the plurality of gain mediums 604a-604d, such that the first output 614 of the coupler 610 forms a part of each of the plurality of laser cavities 602a-602d. For example, the first optical path that forms the first laser cavity 602a includes the first input 612a and the first output 614 of the coupler 610, the second optical path that forms the second laser cavity 602b includes the second input 612b and the first output 614 of the coupler 610, the third optical path that forms the third laser cavity 602c includes the third input 612c and the first output 614 of the coupler 610, and the fourth optical path that forms the fourth laser cavity 602d includes the fourth input 612d and the first output 614 of the coupler 610.

The components of the coupled cavity laser 601 may be divided between different photonic dies of the photonic integrated circuit 600. For example, the photonic integrated circuit 600 may include a first photonic die 620 and a second photonic die 630, which may be configured in any manner as described herein. For example, each of the plurality of gain mediums 604a-604b may be formed along some or all a corresponding gain waveguide of a plurality of gain waveguides (e.g., the first gain medium 604b is formed along some or all of a first gain waveguide, the second gain medium 604b is formed along some or all of a second gain waveguide, the third gain medium 604c is formed along some or all of a third gain waveguide, and the fourth gain medium 604d is formed along some or all of a fourth gain waveguide), such as described herein with respect to FIGS. 3A and 3B. The plurality of gain waveguides may be formed as part of a single photonic die (e.g., the first photonic die 620) or distributed across multiple photonic dies (e.g., a plurality of first photonic dies). In some variations, the coupler 610 is formed in the second photonic die 630, and each of the plurality of inputs 612a-612d of the coupler 610 is formed by a respective input waveguide of the second photonic die 630 (e.g., the first input 612a is formed by a first input waveguide, a second input 612b is formed by a second input waveguide, and so on), such as described herein with respect to FIGS. 3A and 3B. Additionally, the first output 614 of the coupler 610 may be formed by an output waveguide of the second photonic die 630, and the shared partial reflector may be positioned along the output waveguide.

To control operation of the coupled cavity laser 601, a controller (e.g., the controller 402 of the photonic system 400) may drive each of the plurality of gain mediums 604a-604d with a corresponding drive current to operate the plurality of gain mediums 604a-604d. For example, the controller may drive the first gain medium 604a with a first drive current, may drive the second gain medium 604b with a second drive current, may drive the third gain medium 604c with a third drive current, and may drive the fourth gain medium 604d with a fourth drive current. These drive currents may be selected to control the respective effective refractive indices of the plurality of laser cavities 602a-602d, which may in turn control the output power and wavelength of light emitted by the coupled cavity laser 601. In some variations, the controller may utilize one or more feedback signals, such as described herein with respect to FIG. 4A, to control operation of the coupled cavity laser 601.

In some variations, the coupled cavity laser 601 may include a plurality of controllable phase shifters 611a-611c that are operable to change the relative phase of light entering the coupler 610 via the plurality of inputs 612a-612d. For example, the plurality of controllable phase shifters 611a-611c may include a first controllable phase shifter 611a positioned along the first optical path of the first laser cavity 602a between the first reflecting mirror 608a and the coupler 610, a second controllable phase shifter 611b positioned along the second optical path of the second laser cavity 602b between the second reflecting mirror 608b and the coupler 610, and a third controllable phase shifter 611c positioned along the third optical path between the third reflecting mirror 608c and the coupler 610. The plurality of controllable phase shifters 611a-611c are collectively operable to provide any relative phases of light entering the coupler 610 between the first input 612a, the second input 612b, the third input 612c, and the fourth input 612d. In some variations, the plurality of controllable phase shifters 611a-611c may further include a fourth phase shifter (not shown) positioned along the fourth optical path between the fourth reflecting mirror 608d and the coupler 610. The controller may, as part of operating the coupled cavity laser 601, adjust the respect phase shift provided by the each of the plurality of controllable phase shifters 611a-611c.

In other variations, instead of a single N×1 coupler 610, the coupled cavity laser 601 may include a plurality of cascaded couplers. For example, FIG. 6B shows a schematic view of a variation of a photonic integrated circuit 650 having a coupled cavity laser 651. The coupled cavity laser 651 includes a plurality of gain mediums 604, a shared partial reflector 606, and plurality of reflecting mirrors 608a-608d, such as described with respect to the coupled cavity laser 601 of FIG. 6A. The coupled cavity laser 651 includes a set of couplers that includes a plurality of couplers 660a-660c. The plurality of couplers 660a-660c is configured to optically couple each of the plurality of gain mediums 604a-604d to the shared partial reflector 606. To that end, the plurality of couplers 660a-660c includes a plurality of inputs 662a-662d and a first output 664a, where each of the plurality of inputs 662a-662d is optically connected to the first output 664a. The shared partial reflector 606 may be positioned along first output 664a, such that the plurality of couplers 660a-660c optically couples each of the plurality of inputs 662a-662d to the shared partial reflector 606.

In the variation shown in FIG. 6B, the plurality of couplers 660a-660c include a first coupler 660a, a second coupler 660b, and a third coupler 660c. Each of the plurality of couplers 660a-660c may include a corresponding first input, second input, and a first output. In some variations, some or all of the plurality of couplers 660a-660c may be configured as 2×1 couplers. In some variations, one or more of the plurality of couplers 660a-660c may be configured as a 2×2 coupler, in which case each of these couplers include a corresponding second output. In the variation shown in FIG. 6B, the plurality of couplers 660a-660c may be cascaded. Specifically, a first input 662a and a second input 662b of the plurality of inputs 662a-662b may form respective first and second inputs of the first coupler 660a. A first output 668a of the first coupler 660a may form a first input of the third coupler 660c. Similarly, a third input 662c and a fourth input 662d of the plurality of inputs 662a-662b may form respective first and second inputs of the second coupler 660b. A first output 669a of the second coupler 660b may form a second input of the third coupler 660c. A first output of the third coupler 660c may form the first output 664a of the plurality of couplers 660a-660c.

In some variations, such as when the first coupler 660a is configured as a 2×2 coupler (e.g., a directional coupler) the first coupler 660a also includes a second output 668b. In these variations, optical losses associated with the first coupler 660a (e.g., due to power mismatches between the inputs of the first coupler 660a during operation of the coupled cavity laser 651) may be routed to the second output 668b of the first coupler 660a. In some of these variations, the second output 668b may be configured to operate as a dump port (e.g., the second output 668b may include a corresponding light absorbing region 667a as described herein). Additionally or alternatively, the second coupler 660b may be configured as a 2×2 coupler (e.g., a directional coupler) and also includes a second output 669b. In these variations, optical losses associated with the second coupler 660b (e.g., due to power mismatches between the inputs of the second coupler 660b during operation of the coupled cavity laser 651) may be routed to the second output 669b of the second coupler 660b. In some of these variations, the second output 669b may be configured to operate as a dump port (e.g., the second output 669b may include a corresponding light absorbing region 667b as described herein). Additionally or alternatively, the third coupler 660c may be configured as a 2×2 coupler (e.g., a directional coupler) and also includes a second output 664b. In these variations, optical losses associated with the third coupler 660c (e.g., due to power mismatches between the inputs of the third coupler 660c during operation of the coupled cavity laser 651) may be routed to the second output 664b of the third coupler 660c. In some of these variations, the second output 664b may be configured to operate as a dump port (e.g., the second output 664b may include a corresponding light absorbing region 667c as described herein). It should be appreciated that the various inputs and outputs of the couplers 660a-660c may be formed by corresponding waveguides in the photonic integrated circuit 650. For example, in the variation shown in FIGS. 6B, the photonic integrated circuit 650 may include a first photonic die 620 (or a plurality of first photonic dies) and a second photonic die 630 as described herein, and each of the plurality of couplers 660a-660c is positioned in the second photonic die 630. In other instances, each of the plurality of couplers 660a-660c is positioned in the first photonic die 620. In other instances, one or more of the plurality of couplers 660a-660c are positioned in the first photonic die 620 (or distributed between a plurality of first photonic dies) and one or more of the plurality of couplers 660a-660c are positioned in the second photonic die 630.

The coupled cavity laser 651 may define a plurality of laser cavities 652a-652b using the plurality of couplers 660a-660c. Specifically, a first laser cavity 652a may be defined by a first optical path extending between the shared partial reflector 606 and the first reflecting mirror 608a. The first optical path may include the first gain medium 604a, the first input of the first coupler 660a (e.g., first input 662a of the plurality of inputs 662a-662d), the first output 668a of the first coupler 660a, and the first output of the third coupler 660c (e.g., the first output 664a). A second laser cavity 652b may be defined by a second optical path extending between the shared partial reflector 606 and the second reflecting mirror 608b. The second optical path may include the second gain medium 604b, the second input of the first coupler 660a (e.g., second input 662 of the plurality of inputs 662a-662d), the first output 668a of the first coupler 660a, and the first output of the third coupler 660c (e.g., the first output 664a).

Similarly, a third laser cavity 652c may be defined by a third optical path extending between the shared partial reflector 606 and the third reflecting mirror 608c. The third optical path may include the third gain medium 604c, the first input of the second coupler 660b (e.g., third input 662c of the plurality of inputs 662a-662d), the first output 669a of the second coupler 660b, and the first output of the third coupler 660c (e.g., the first output 664a). A fourth laser cavity 652d may be defined by a fourth optical path extending between the shared partial reflector 606 and the fourth reflecting mirror 608d. The fourth optical path may include the fourth gain medium 604d, the second input of the second coupler 660b (e.g., fourth input 662d of the plurality of inputs 662a-662d), the first output 669a of the second coupler 660b, and the first output of the third coupler 660c (e.g., the first output 664a).

The first output 668a of the first coupler 660a may form a shared portion of the first and second optical paths of the first laser cavity 652a and the second laser cavity 652b, respectively, between the first coupler 660a and the third coupler 660c. The first output 669a of the second coupler 660b may form a shared portion of the third and fourth optical paths of the third laser cavity 652c and the fourth laser cavity 652d, respectively, between the second coupler 660b and the third coupler 660c. The first output of the third coupler 660c (e.g., the first output 664a of the plurality of couplers 660a-660c) may form a shared portion of the corresponding optical paths of each of the plurality of laser cavities 652a-652d between the third coupler 660c and the shared partial reflector 606. Overall, light traveling in different laser cavities may travel through different combinations of couplers of the plurality of couplers 660a-660c.

To control operation of the coupled cavity laser 651, a controller (e.g., the controller 402 of the photonic system 400) may drive each of the plurality of gain mediums 604a-604d with a corresponding drive current to operate the plurality of gain mediums 604a-604d. For example, the controller may drive the first gain medium 604a with a first drive current, may drive the second gain medium 604b with a second drive current, may drive the third gain medium 604c with a third drive current, and may drive the fourth gain medium 604d with a fourth drive current. These drive currents may be selected to control the respective effective refractive indices of the plurality of laser cavities 652a-652d, which may in turn control the output power and wavelength of light emitted by the coupled cavity laser 601. In some variations, the controller may utilize one or more feedback signals, such as described herein with respect to FIG. 4A, to control operation of the coupled cavity laser 601.

In some variations, the coupled cavity laser 601 may include a plurality of controllable phase shifters 661a-661c that are each operable to change the relative phase of light entering a corresponding coupler of the plurality of couplers 660a-660c. For example, the plurality of controllable phase shifters 661a-661c may include a first controllable phase shifter 661a, a second controllable phase shifter 661b, and a third controllable phase shifter 661c. The first controllable phase shifter 661a may be positioned along the first optical path of the first laser cavity 652a between the first reflecting mirror 608a and the first coupler 660a. Specifically, the first controllable phase shifter 661a is positioned to adjust a corresponding phase of light entering the first input of the first coupler 610a. The first controllable phase shifter 661a may be operable (e.g., as controlled by a controller as described herein) to adjust the relative phase of light entering the inputs of the first coupler 660a (e.g., via the first input 662a and the second input 662b of the plurality of inputs 662a-662d). Accordingly, a first target phase shift for the first controllable phase shifter 661a may be selected to reduce loss associated with light coupling between the inputs and first output 668a of the first coupler 660a.

The second controllable phase shifter 6161b may be positioned along the fourth optical path of the fourth laser cavity 652d between the fourth reflecting mirror 608d and the second coupler 660b. Specifically, the second controllable phase shifter 661b is positioned to adjust a corresponding phase of light entering the second input of the second coupler 660b. The second controllable phase shifter 661b may be operable (e.g., as controlled by a controller as described herein) to adjust the relative phase of light entering the inputs of the second coupler 660b (e.g., via the third input 662c and the fourth input 662d of the plurality of inputs 662a-662d). Accordingly, a second target phase shift for the second controllable phase shifter 661b may be selected to reduce loss associated with light coupling between the inputs and first output 669a of the second coupler 660b.

The third controllable phase shifter 661c may be positioned along a shared portion of the third and fourth optical paths of the third laser cavity 652c and the fourth laser cavity 652d, respectively, between the second coupler 660b and the third coupler 660c. Specifically, the third controllable phase shifter 661c may be positioned to change a corresponding phase of light traveling through the first output 669a of the second coupler 660b, and thus may be operable to adjust the relative phase entering the inputs of the third coupler 660c (e.g., via the first output 668a of the first coupler 660a and the first output 669a of the second coupler 660b). Accordingly, a third target phase shift for the third controllable phase shifter 661c may be selected to reduce loss associated with light coupling between the inputs and first output 664a of the third coupler 660c. The controller may, as part of operating the coupled cavity laser 651, adjust the respect phase shift provided by the each of the plurality of controllable phase shifters 661a-661c.

It should be appreciated that the coupled cavity laser 651 may include additional phase shifters (e.g., along the second optical path of the second laser cavity 652b between the second reflecting mirror 608a and the first coupler 660a, along the third optical path of the third laser cavity 652c between the third reflecting mirror 608c and the second coupler 660b, and/or along a shared portion of the first and second optical paths of the respective first and second laser cavities 652a, 652b between the first coupler 660a and the third coupler 660c). This may provide the coupled cavity laser 651 with additional flexibility in controlling the relative phase of light entering the first coupler 660a, the second coupler 660b, and/or the third coupler 660c.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. A photonic system, comprising:
a photonic integrated circuit, comprising:
a first photonic die, comprising:
a first gain medium;
a second gain medium;
a first reflecting mirror; and
a second reflecting mirror;
a second photonic die comprising:
a shared partial reflector; and
a coupler optically connecting the first gain medium and the second gain medium to the shared partial reflector; and
a coupled cavity laser defining a first laser cavity and a second laser cavity, wherein:
the first laser cavity comprises the first reflecting mirror, the first gain medium, and the shared partial reflector; and
the second laser cavity comprises the second reflecting mirror, the second gain medium, and the shared partial reflector.

2. The photonic system of claim 1, wherein the coupler is a directional coupler.

3. The photonic system of claim 1, wherein the coupler is a multi-mode interference coupler.

4. The photonic system of claim 1, wherein the shared partial reflector is a distributed Bragg reflector.

5. The photonic system of claim 1, wherein the photonic integrated circuit comprises a controllable phase shifter positioned along an optical path of the first laser cavity between the first reflecting mirror and the coupler.

6. The photonic system of claim 5, wherein the controllable phase shifter is positioned in the second photonic die.

7. The photonic system of claim 1, comprising a controller configured to control the coupled cavity laser to emit output light from the shared partial reflector.

8. The photonic system of claim 7, comprising an optical monitor configured to receive a portion of the output light emitted by the coupled cavity laser and generate one or more feedback signals, wherein:
the controller is configured to control the coupled cavity laser using the one or more feedback signals.

9. The photonic system of claim 1, wherein the second laser cavity comprises a delay line positioned between the second reflecting mirror and the coupler.

10. The photonic system of claim 9, wherein the delay line is configured to provide a wavelength dependent periodic loss filter to the coupled cavity laser.

11. A photonic integrated circuit comprising:
a coupled cavity laser comprising:
a plurality of gain mediums;
a plurality of reflecting mirrors; and
a shared partial reflector, wherein:
the coupled cavity laser defines a plurality of laser cavities; and
each laser cavity of the plurality of laser cavities comprises:
a corresponding gain medium of the plurality of gain mediums;
a corresponding reflecting mirror of the plurality of reflecting mirrors; and
the shared partial reflector.

12. The photonic integrated circuit of claim 11, comprising a set of couplers optically connecting the plurality of gain mediums to the shared partial reflector.

13. The photonic integrated circuit of claim 12, wherein the set of couplers comprises a N×1 coupler.

14. The photonic integrated circuit of claim 13, wherein the N×1 coupler is a 4×1 coupler.

15. The photonic integrated circuit of claim 12, wherein the set of couplers comprises a plurality of couplers.

16. The photonic integrated circuit of claim 15, wherein the plurality of couplers comprises:
a first coupler comprising a first input, a second input, and a first output;
a second coupler comprising a first input, a second input, and a first output;
a third coupler comprising:
a first input connected to the first output of the first coupler;
a second input connected to the first output of the second coupler; and
a first output.

17. The photonic integrated circuit of claim 16, comprising:
a first controllable phase shifter positioned to control a corresponding phase of light in the first input of the first coupler;
a second controllable phase shifter positioned to control a corresponding phase of light in the second input of the second coupler; and
a third controllable phase shifter positioned to control a corresponding phase of light in the first output of the second coupler.

18. A photonic integrated circuit comprising:
a set of first photonic dies comprising:
a plurality of gain mediums; and
a plurality of reflecting mirrors;
a second photonic die comprising:
a shared partial reflector; and
a coupled cavity laser defining a plurality of laser cavities, wherein each laser cavity of the plurality of laser cavities comprises:
a corresponding gain medium of the plurality of gain mediums;
a corresponding reflecting mirror of the plurality of reflecting mirrors; and
the shared partial reflector.

19. The photonic integrated circuit of claim 18, comprising a coupler optically connecting the plurality of gain mediums to the shared partial reflector.

20. The photonic integrated circuit of claim 19, wherein the second photonic die comprises the coupler.
